(19) United States
(12) Patent Application Publication
(10) Pub. No.: US 2023/0331915 A1
(43) Pub. Date: Oct. 19, 2023

(54) Isocyanate-Modified Polyimide Resin, Resin Composition and Cured Product of Same

(71) Applicant: Nippon Kayaku Kabushiki Kaisha, Tokyo (JP)

(72) Inventors: Ryutaro Tanaka, Tokyo (JP); Chie Sasaki, Tokyo (JP); Noriyuki Nagashima, Tokyo (JP)

(21) Appl. No.: 18/013,334

(22) PCT Filed: Jun. 25, 2021
(86) PCT No.: PCT/JP2021/024103

§ 371 Date: Dec. 28, 2022

(30) Foreign Application Priority Data
Jun. 29, 2020 (JP) 2020-111578
Dec. 22, 2020 (JP) 2020-211917

(51) Int. Cl. C08G 73/10

(52) U.S. Cl. CPC C08G 73/10

(57) ABSTRACT

An isocyanate-modified polyimide resin is a reaction product of a diisocyanate compound (a) having an isocyanate group and a polyimide resin having an amino group and/or an acid anhydride group. The polyimide resin is a reaction product of an aliphatic diamino compound (b), a tetrabasic acid dianhydride (c) and an aromatic diamino compound (c). The isocyanate-modified polyimide has an amino group and/or an acid anhydride group on both ends. This isocyanate-modified polyimide resin is a resin material having a novel structure, and is suitable for use in a printed wiring board. A cured product which is obtained using this resin material has a low dielectric loss tangent, while being excellent in terms of adhesiveness, heat resistance and mechanical property.

### CROSS-REFERENCE TO RELATED APPLICATIONS

This application is the United States national phase of International Application No. PCT/JP2021/024103 filed Jun. 25, 2021, and claims priority to Japanese Patent Application Nos. 2020-111578 filed Jun. 29, 2020 and 2020-211917 filed Dec. 22, 2020, the disclosures of which are hereby incorporated by reference in their entirety.

### BACKGROUND OF THE INVENTION

### Field of the Invention

The present invention relates to an isocyanate-modified polyimide resin having a novel structure, a resin composition containing the polyimide resin and a cured product of the resin composition.

### Description of Related Art

As an essential member for the mobile communication devices such as smartphone (mobile phone) and tablet computer, the communication base station apparatus and the electronics such as computer and car navigation device, there is a printed wiring board. Various resin materials excellent in the characteristics such as low roughness metal foil adhesion, heat resistance and flexibility are used for the printed wiring board.

Recently, the printed wiring board for the high-speed and large-capacity next-generation high frequency radio communication device has been developed. The resin material having low transmission loss, namely low dielectric constant and low dielectric loss tangent in addition to the characteristics described above is required.

The polyimide resin excellent in the characteristics such as heat resistance, flame resistance, flexibility, electric property and chemical resistance is widely used for an electric-electronic parts, a semiconductor, a communication device and a circuit part thereof, a peripheral device and the like. The hydrocarbon compounds derived from petroleum and natural oil are known to exhibit high insulating property and low dielectric constant. In view of the characteristics of the both, the polyimide resin having a structure into which a long chain alkylene skeleton derived from dimer diamine is introduced is described in Patent Documents 1 to 4.

But the polyimide resin described in these Patent Documents is excellent because it has a low dielectric loss tangent but inferior in the balance between low dielectric loss tangent and various characteristics such as workability, flexibility, heat resistance, adhesiveness and mechanical property.

### CITATION LIST

### Patent Document

Patent Document 1: JP 5,534,378 B

Patent Document 2: JP 6,488,170 B

Patent Document 3: JP 6,635,403 B

Patent Document 4: JP 6,082,439 B

### SUMMARY OF INVENTION

### Technical Problem

One of the purposes of the present invention is to provide a rein material which has a novel structure and can be suitably used for a printed wiring board, a resin composition which contains the resin material and has excellent workability, and a cured product having a low dielectric constant and a low dielectric loss tangent and is excellent in adhesiveness, heat resistance and mechanical property.

### Solution to Problem

By the earnest research, the present inventors found to solve the problems by using a resin composition containing a novel polyimide resin having the specific structure so as to finish the present invention.

That is, the present invention relates to:
[1] An isocyanate-modified polyimide resin being a reaction product of a diisocyanate compound (a) having an isocyanate group and a polyimide resin having an amino group and/or an acid anhydride group, wherein the polyimide resin is a reaction product of an aliphatic diamino compound (b), a tetrabasic acid dianhydride (c) and an aromatic diamino compound (d), and wherein the isocyanate-modified polyimide has an amino group and/or an acid anhydride group on both ends.
[2] The isocyanate-modified polyimide resin according to item [1], wherein the diisocyanate compound (a) comprises at least one selected from the group consisting of hexamethylenediisocyanate, trimethylhexamethylenediisocyanate and isophoronediisocyanate.
[3] The isocyanate-modified polyimide resin according to item [1] or [2], wherein the aliphatic diamino compound (b) comprises at least one of aliphatic diamino compounds having a carbon number of 6 to 36
[4] The isocyanate-modified polyimide resin according to any one of items [1] to [3], wherein the tetrabasic acid dianhydride (c) comprises at least one selected from the group consisting of the compounds represented by following formulas (1) to (4):

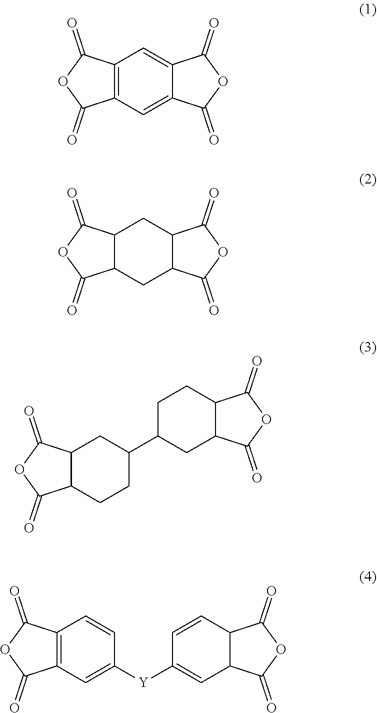

wherein in formula (4), Y represents C(CF₃)₂, SO₂, CO, O, a direct bond or a bivalent linking group represented by following formula (5):

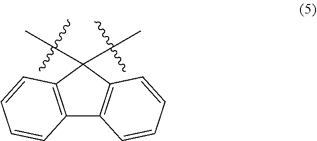 [SMILES: *C1(*)c2ccccc2-c2ccccc21]

[5] The isocyanate-modified polyimide resin according to any one of items [1] to [4], wherein the aromatic diamino compound (d) comprises at least one selected from the group consisting of the compounds represented by following formulas (6) and (8):

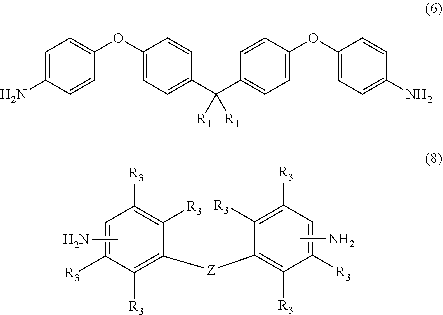

wherein in formula (6), R₁ represents methyl group or trifluoromethyl group, in formula (8), Z represents CH(CH₃), C(CF₃)₂, SO₂, CH₂, O—C₆H₄—O, O, a direct bond or a bivalent linking group represented by following formula (9):

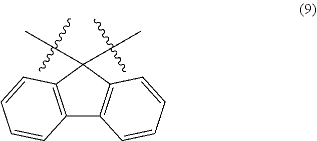

wherein R₃ represents hydrogen atom, methyl group, ethyl group, hydroxy group or trifluoromethyl group.
[6] A terminal-modified isocyanate-modified polyimide resin being a reaction product of the isocyanate-modified polyimide resin having an amino group and/or an acid anhydride group on both ends according to any one of items [1] to [5] and a compound having one functional group capable of reacting with the amino group or the acid anhydride group.
[7] A resin composition comprising the isocyanate-modified polyimide resin according to any one of items [1] to [5] and a compound reactive with the isocyanate-modified polyimide resin.
[8] A resin composition comprising the terminal-modified isocyanate-modified polyimide resin according to item [6] and a compound reactive with the terminal-modified isocyanate-modified polyimide resin.
[9] The resin composition according to item [7] or [8], wherein the compound reactive with the isocyanate-modified polyimide resin or the compound reactive with the terminal-modified isocyanate-modified polyimide resin comprises at least one of compounds having a maleimide group.
[10] A resin composition comprising the isocyanate-modified polyimide resin according to any one of items [1] to [5] and the compound nonreactive with the isocyanate-modified polyimide resin.
[11] A resin composition comprising the terminal-modified isocyanate-modified polyimide resin according to item [6] and a compound nonreactive with the terminal-modified isocyanate-modified polyimide resin.
[12] A cured product of the resin composition according to any one of items [7] to [11].
[13] A substrate having the cured product according to item [12].

### DESCRIPTION OF THE INVENTION

By using the resin composition containing the isocyanate-modified polyimide resin of the present invention having a specific structure, the printed wiring board and the like excellent in heat resistance, mechanical property, low dielectric property, adhesiveness and the like can be provided.

The isocyanate-modified polyimide resin of the present invention is an isocyanate-modified polyimide resin obtained by reacting an isocyanate group of a diisocyanate compound (a) (hereinafter, simply described as “component (a)”) with an amino group and/or an acid anhydride group which the polyimide resin has on both ends (hereinafter, the polyimide resin which is the reaction product of the components (b) to (d) is simply described as “intermediate polyimide resin”), the polyimide resin being a reaction product of the aliphatic diamino compound (b)(hereinafter, simply described as “component (b)”), the tetrabasic acid dianhydride (c) (hereinafter, simply described as “component (c)”) and the aromatic diamino compound (d) (hereinafter, simply described as “component (d)”), wherein the isocyanate-modified polyimide resin has an amino group and/or an acid anhydride group on both ends.

[Intermediate Polyimide Resin]

First, the intermediate polyimide resin is described.

The reaction of the components (b) to (d) includes a step in which the polyamic-acid is obtained by the copolymerization reaction of the amino groups of the components (b) and (d) and the acid anhydride group of the component (c), and a step in which the intermediate polyimide resin is obtained by the dehydrocyclization reaction (imidation reaction) of the polyamic-acid. The two steps above may be carried out separately, but it is efficient that the two steps are carried out successively.

When the components (b), (c) and (d) are used for the copolymerization reaction and the mol number MB of the component (b), the mol number MC of the component (c) and the mol number MD of the component (d) satisfy the relationship MB+MD>MC, the both ends of the intermediate polyimide resin obtained are amino groups. When MB, MC and MD satisfy the relationship MB+MD<MC, the both ends of the intermediate polyimide resin obtained are acid anhydride groups. When MB, MC and MD satisfy the relationship MB+MD=MC, the molecular weight of the intermediate polyimide resin obtained is theoretically infinity and the intermediate polyimide resin has one amino group on one end and one acid anhydride group on the other end.

The amount of the component (b) used for the copolymerization reaction is not particularly limited, preferably the component (b) is preferably within the range of 10 to 50 mass % of the mass (this mass is substantially equal to the mass of the isocyanate-modified polyimide resin obtained in the end) obtained by subtracting the mass of the water generated in the dehydrocyclization reaction step during synthesizing the intermediate polyimide resin from the total mass of the components (b) to (d) used in the step of synthesizing the intermediate polyimide resin and the mass of the component (a) used in the step of synthesizing the isocyanate-modified polyimide resin described below. When the amount of the component (b) is below the range aforementioned, the proportion of the aliphatic chain derived from the component (b) in the intermediate polyimide resin is too low, therefore, the dielectric constant and the dielectric loss tangent may become high. When the amount of the component (b) is above the range aforementioned, the proportion of the aliphatic chain derived from the component (b) in the intermediate polyimide resin is too high, therefore, the heat resistance of the cured product may be decreased.

The component (b) used for synthesizing the intermediate polyimide resin is not particularly limited as long as the component (b) is an aliphatic compound having two amino groups in one molecular, and preferably the component is an aliphatic diamino compound having a carbon number of 6 to 36. Examples of the component (b) include hexamethylenediamine, 1,3-bis(aminomethyl)cyclohexane, C14 branched diamine, C18 branched diamine, dimer diamine and diaminopolysiloxane. These may be used alone or in mixture of two or more.

In this specification, the dimer diamine described as the example of the component (b) is a compound obtained by substituting the primary amino group for two carboxy groups of the dimer acid which is the dimer of the unsaturated fatty acids such as oleic acid (see JP H9-12712 A and the like). Examples of the commercial products of dimer diamine include PRIAMINE1074 and PRIAMINE1075 (both manufactured by Croda Japan K.K.) and Versamine551 (manufactured by Cognis Japan Ltd.). These may be used alone or in mixture of two or more.

The component (c) used for synthesizing the intermediate polyimide resin is not particularly limited as long as the component (c) is a compound having two acid anhydride groups in one molecular. Examples of the component (c) include pyromellitic dianhydride, ethyleneglycol-bis(anhydrotrimellitate), glycerin-bis(anhydrotrimellitate)monoacetate, 1,2,3,4-butanetetracarboxylic acid dianhydride, 3,3′,4,4′-diphenylsulfonetetracarboxylic acid dianhydride, 3,3′,4,4′-benzophenonetetracarboxylic acid dianhydride, 3,3′,4,4′-biphenyltetracarboxylic acid dianhydride, 3,3′,4,4′-diphenylethertetracarboxylic acid dianhydride, 5-(2,5-dioxotetrahydro-3-furanyl)-3-methylcyclohexene-1,2-dicarboxylic acid anhydride, 3a,4,5,9b-tetrahydro-5-(tetrahydro-2,5-dioxo-3-furanyl)-1,3-dione, 1,2,4,5-cyclohexanetetracarboxylic acid dianhydride, bicyclo(2,2,2)-octo-7-ene-2,3,5,6-tetracarboxylic acid dihydride and bicyclo[2,2,2]octane-2,3,5,6-tetracarboxylic acid dihydride and 5,5′-((propane-2,2-diylbis(4,1-phenylene))bis(oxy))bis(isobenzofuran-1,3-dione). Among them in terms of solubility in solvent, adhesion to the substrate and photosensitivity 3,3′,4,4′-diphenylsulfonetetracarboxylic acid dianhydride, 3,3′,4,4′-benzophenonetetracarboxylic acid dianhydride, 3,3′,4,4′-biphenyltetracarboxylic acid dianhydride or 3,3′,4,4′-diphenylethertetracarboxylic acid dianhydride are preferable. These may be used alone or in mixture of two or more.

The component (c) used for synthesizing the intermediate polyimide resin preferably includes at least one compound selected from the group consisting of the compounds represented by following formulas (1) to (4).

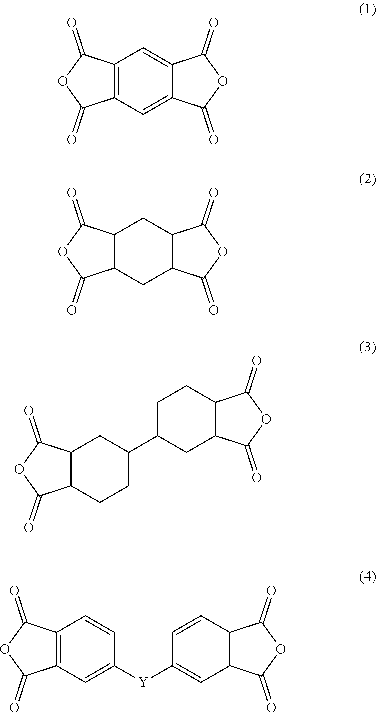

In formula (4), Y represents C(CF₃)₂, SO₂, CO, O, a direct bond or a bivalent linking group represented by the following formula (5). Note that two linking parts represented by formula (5) are the parts each bonding to 2-benzofuran.

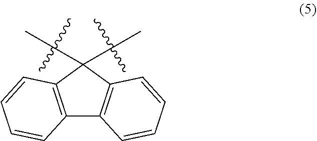 [SMILES: *C1(*)c2ccccc2-c2ccccc21]

The component (d) used for synthesizing the intermediate polyimide resin is not particularly limited as long as the component (d) is an aromatic compound having two amino groups in one molecular. Examples of the compound (d) includes m-phenylenediamine, p-phenylenediamine, m-tolylenediamine, 4,4′-diaminodiphenylether, 3,3′-dimethyl-4,4′-diaminodiphenylether, 3,4′-diaminodiphenylether, 4,4′-diaminodiphenylthioether, 3,3′-dimethyl-4,4′-diaminodiphenylthioether, 3,3′-diethoxy-4,4′-diaminodiphenylthioether,3,3′-diaminodiphenylthioether, 4,4′-diaminobenzophenone, 3,3′-dimethyl-4,4′diaminobenzophenone, 3,3′-diaminodiphenylmethane, 4,4′-diaminodiphenylmethane, 3.4′-diaminodiphenylmethane, 3,3′-dimethoxy-4,4′-diaminodiphenylthioether, 2,2′-bis(3-aminophenyl)propane, 2,2′-bis(4-aminophenyl)propane, 4,4′-diaminodiphenylsufoxide, 3,3′-diaminodiphenylsulfone, 4,4′-diaminodiphenylsulfone, benzidine, 3,3′-dimethylbenzidine, 3,3′-dimethoxybenzidine, 3,3′-diaminobiphenyl, p-xylylenediamine, m-xylylenediamine, o-xylylenediamine, 2,2′-bis(3-aminophenoxyphenyl)propane, 2,2′-bis(4-aminophenoxyphenyl)propane, 1,3-bis(4-aminophenoxyphenyl)benzene, 1,3′-bis(3-aminophenoxyphenyl)propane, bis(4-amino-3-methylphenyl)methane, bis(4-amino-3,5-dimethylphenyl)methane, bis(4-amino-3-ethylphenyl)methane, bis(4-amino-3,5-diethylphenyl)methane, bis(4-amino-3-propylphenyl)methane and bis(4-amino-3,5-dipropylphenyl)methane. These may be used alone or in mixture of two or more.

The component (d) used for synthesizing the intermediate polyimide resin preferably includes at least one compound selected from the group consisting of the compounds represented by the following formulas (6) and (8):

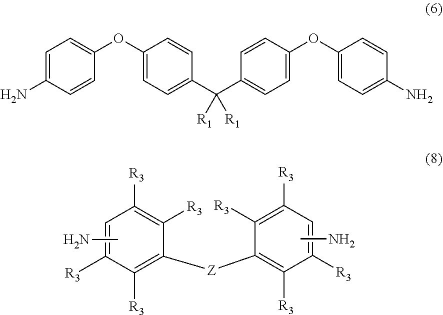

In formula (6), R₁ represents methyl group or trifluoromethyl group, in formula (8), Z represents CH(CH₃), SO₂, CH₂, O—C₆H₄—O, O, a direct bond or a bivalent linking group represented by following formula (9), R₃ represents hydrogen atom, methyl group, ethyl group, or trifluoromethyl group. Note that the two linking parts represented by formula (9) are the parts each bonding to 2-benzofuran.

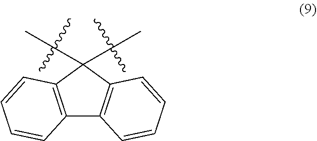 [SMILES: *C1(*)c2ccccc2-c2ccccc21]

The intermediate polyimide resin can be synthesized by conventional methods.

For example, a solvent, a dehydrating agent and a catalyst are added to the mixture of components (b) to (d) used for synthesis. By stirring and heating the mixture under the atmosphere of the inert gas such as nitrogen at 100 to 300° C., the imidation reaction (the ring closure reaction accompanied by the dehydration) occurs through polyamic-acid to obtain the intermediate polyimide resin solution. By distilling the water generated in the imidation away to the outside of the system at this time and distilling the dehydrating agent and the catalyst after the reaction, the high purity intermediate polyimide resin can be obtained without requiring washing. Examples of the dehydrating agent includes toluene and xylene and the catalyst includes pyridine and triethylamine.

Examples of the solvent used in the synthesis of the intermediate polyimide resin includes methylethylketone, methypropylketone, methyisopropylketone, methylbutylketone, methylisobutylketone, methyl-n-hexylketone, diethylketone, diisopropylketone, diisobutylketone, cyclopentanone, cyclohexanone, methylcyclohexanone, acetylacetone, γ-butylolactone, diacetonealcohol, cyclohexene-1-one, dipropylether, diisopropylehter, dibutylether, tetrahydrofuran, tetrahydropyran, ethylisoamylether, ethyl-t-butylether, ethylbenzylether, cresylmethylether, anisole, phenetole, methyl acetate, ethyl acetate, propyl acetate, isopropyl acetate, butyl acetate, isobutyl acetate, amyl acetate, isoamyl acetate, 2-ethylhexyl acetate, cyclohexyl acetate, methylcyclohexyl acetate, benzyl acetate, methyl acetoacetate, ethyl acetoacetate, methyl propionate, ethyl propionate, butyl propionate, benzyl propionate, methyl butyrate, ethyl butyrate, isopropyl butyrate, butyl butyrate, isoamyl butyrate, methyl lactate, ethyl lactate, butyl lactate, ethyl isovalerate, isoamyl isovalerate, diethyl oxalate, dibutyl oxalate, methyl benzoate, ethyl benzoate, propyl benzoate, methyl salicylate, N-methylpyrolidone, N, N-dimethylformamide, N, N-dimethylacetoamide, dimethylsulfoxide but is not limited to these. These may be used alone or in mixture of two or more.

[Isocyanate-Modified Polyimide Resin]

Next, the isocyanate-modified polyimide resin of the present invention is described.

The isocyanate-modified polyimide resin of the present invention is obtained by the reaction of the intermediate polyimide resin and the component (a). The reaction of the intermediate polyimide resin and the component (a) is the copolymerization reaction of the amino group or the acid anhydride group that the intermediate polyimide resin has on the ends and the isocyanate group which the component (a) has. The urea bond is formed by the reaction of the amino group and the isocyanate group. The imide bond is formed by the reaction of the acid anhydride group and the isocyanate group.

The amount of the component (a) used for the copolymerization reaction of the intermediate polyimide resin and the component (a) is the amount satisfying conditions that the isocyanate group of the component (a) is preferably less than 1 equivalent based on 1 equivalent of the terminal functional group of the intermediate polyimide resin, more preferably 0.50 to 0.99 equivalent, further preferably 0.67 to 0.98 equivalent. When the amount of the component (a) based on the intermediate polyimide resin is within the range aforementioned, thereby the isocyanate-modified polyimide resin has the high molecular weight as well as the remaining rate of the unreacted raw material is lowered. As a result, the various characteristics such as heat resistance and flexibility after curing the resin composition containing the isocyanate-modified polyimide resin, the polyimide resin and the like are improved.

Note that the equivalent of the terminal functional group of the intermediate polyimide resin herein means the value calculated from the used amount of each raw material when synthesizing the intermediate polyimide resin.

As the component (a) used for the synthesis of the isocyanate-modified resin of the present invention, all the compounds having two isocyanate groups in one molecular can be used. Also, at the same time, more than one diisocyanate compounds can be reacted. As the component (a), phenylenediisocyanate, tolylenediisocyanate, xylylenediisocyanate, tetramethylxylylenediisocyanate, diphenylmethanediisocyanate, naphthalenediisocyanate, trienediisocyanate, hexamethylenediisocyanate, dicyclohexylmethanediisocyanate, isophoronediisocyanate, allylenesulfoneetherdiisocyanate, allylsilanediisocyanate, N-acyldiisocyanate, trimethylhexamethylenediisocyanate, 1,3-bis(isocyanatemethyl)cyclohaxane or norbornane-diisocyanatemethyl are preferable. Among them, hexamethylenediisocyanate, trimethylhexamethylenediisocyanate, or isophoronediisocyanate which are excellent in the balance of flexibility, adhesiveness and the like are more preferable.

The reaction of the intermediate polyimide resin and the component (a) should be carried out by the conventional synthetic method.

Specifically, the component (a) is added to the intermediate polyimide resin solution obtained by the synthetic method described above and the mixture is stirred and heated at 80 to 150° C. to obtain the isocyanate-modified polyimide resin of the present invention. Note that the reaction times of the synthetic reaction of the intermediate polyimide resin and the reaction of the intermediate polyimide resin and the component (a) are greatly affected by the reaction temperature. But the reaction is preferably carried out until the viscosity increase accompanied by the progress of the reaction reaches equilibrium to obtain the maximum molecular weight. The reaction time is generally several tens minutes to 20 hours.

After the isocyanate-modified polyimide resin solution obtained above is added into the poor solvents such as water, methanol and hexane to separate the generated polymer, the solid contents of the isocyanate-modified polyimide resin of the present invention also can be obtained by the reprecipitation method.

[Terminal-Modified Isocyanate-Modified Polyimide Resin]

Because the isocyanate-modified polyimide resin of the present invention has an amino group and/or an acid anhydride group on both ends, the terminal can be modified by reacting with the compound having one functional group capable of reacting with these functional groups to prepare the terminal-modified isocyanate-modified polyimide resin. Examples of the compound capable of reacting with an amino group and/or an acid anhydride group include the compounds having an acid anhydride group such as maleic anhydride, the compounds having an alcoholic hydroxy group such as hydroxyethylacrylate, the compounds having a phenolic hydroxy group such as phenol, the compounds having an isocyanate group such as 2-methacryloyloxyethylisocyanate and the compounds having an epoxy group such as glycidylmethacrylate.

Because the both terminals of the isocyanate compound of the present invention can be changed to the functional group except for the amino group and/or the acid anhydride group by modifying the terminal (for example, when the terminal is modified by using the hydroxyethylacrylate, the terminal of the isocyanate-modified polyimide resin can be changed to the acryloyl group), the compound reactive with the functional group except for the amino group and/or the acid anhydride group also can be combined to obtain the composition.

### [Resin Composition]

The resin composition of the present invention is roughly classified into the first embodiment containing the isocyanate-modified polyimide resin of the present invention and the compounds except for the isocyanate-modified polyimide resin and the second embodiment containing the terminal-modified isocyanate-modified polyimide resin of the present invention and the compounds except for the terminal-modified isocyanate-modified polyimide resin.

First, as the first embodiment, the resin composition of the present invention containing the isocyanate-modified polyimide resin and the compound except for the isocyanate-modified polyimide resin is described.

The compound except for the isocyanate-modified polyimide resin of the resin composition of the first embodiment may be any one of the compound reactive with the isocyanate-modified polyimide resin (hereinafter described as “the reactive compound of the first embodiment”) and the compound nonreactive with the isocyanate-modified polyimide resin (hereinafter described as “the nonreactive compound of the first embodiment”).

The reactive compound of the first embodiment is the compound reactive with the acid anhydride group and/or the amino group that the isocyanate-modified polyimide resin has on the end.

Examples of the reactive compound of the first embodiment reactive with the acid anhydride group include the compound having an epoxy group, the compound having a thiol group and the compound having an amino group. The compound having an epoxy group is preferable.

The compound having an epoxy group is not particularly limited as long as the compound has one or more epoxy groups in one molecular, but is preferably the compound having more than two epoxy groups in one molecular and includes novolac type epoxy resin, bisphenol type epoxy resin, biphenyl type epoxy resin, triphenylmethane type epoxy resin and phenolaralkyl type epoxy resin. Specifically, the compound having an epoxy group includes NC-3000, NC-7000, XD-1000, EOCN-1020, EPPN-502H (all manufactured by Nippon Kayaku Co., Ltd.), jER828, jER807 (manufactured by Mitsubishi Chemical Corporation). NC-3000 or XD-1000 are preferable.

The various thermosetting catalyst may be added to the resin composition of the present invention containing the compound having an epoxy group as the reactive compound of the first embodiment as necessary to promote the curing reaction of the acid anhydride group and the compound having an epoxy group. Examples of the thermosetting catalyst includes imidazoles such as 2-methylimidazole, 2-ethylimidazole, 2-ethyl-4-methylimidazole, 2-phenyl-4,5-dihydroxymethylimidazole and 2-phenyl-4-methyl-5-hydroxymethylimidazole, tertiary amines such as 2-(dimethylaminomethyl)phenol and 1,8-diaza-bicyclo(5,4,0)undecene-7, phosphines such as triphenylphosphine, metal compounds such as tin octylate. The amount of the thermosetting catalyst added in the resin composition of the present invention containing the compound having an epoxy group is 0.1 to 10 mass % based on the compound having an epoxy group.

Note that in the resin composition containing the compound having an epoxy group as the reactive compound of the first embodiment the compounds having reactivity with the epoxy group such as the compound having a phenolic hydroxy group, the compound having an amino group and the compound having an anhydride group can be used together.

The compound having a thiol group is not particularly limited as long as the compound has one or more thiol groups in one molecular, but is preferably the compound having more than two thiol groups, and examples include pentaerythritoltetrakis(3-mercaptobutyrate), 1,4-bis(3-mercaptobutyryloxy)butane, 1,3,5-tris(2-(3-sulfanylbutanoyloxy)ethyl)-1,3,5-triazinane-2,4,6-trione, trimethylolpropanetris(3-mercaptobutyrate), trimethylolpropanetristhiopropionate, pentaerythritoltetrakisthiopropionate, ethyleneglycolbisthioglycolate, 1,4-butanediolbisthioglycolate, trimethylolpropanetristhioglycolate, pentaerythritoltetrakisthioglycolate, di(2-mercaptoethyl)ether, 1,4-butanedithiol, 1,3,5-trimercaptomethylbenzene, 1,3,5-trimercaptomethyl-2,4,6-trimethylbenzene, polyether having the terminal thiol group, polythioether having the terminal thiol group, the thiol compound obtained by the reaction of the epoxy compound and hydrogen sulfide, the thiol compound having the terminal thiol group obtained by the reaction of the polythiol compound and the epoxy compound.

The commercial products of the compound having a thiol group are KarenzMT PE1, KarenzMT NR1, KarenzMT BD1 (all manufactured by Showa Denko K.K.), and so on.

The compound having an amino group is not particularly limited as long as the compound has one or more amino groups in one molecular, but is preferably the compound having more than two amino groups. Examples of the compound having an amino group include hexamethylenediamine, naphthalenediamine, 1,3-bis(aminomethyl)cyclohexane, isophoronediamine, 4,4′-methylenebis(cyclohexylamine) and norbornanediamine.

The reactive compound of the first embodiment reactive with the amino group includes the compound having a maleimide group, the compound having an epoxy group and the compound having a carboxy group. The compound having a maleimide group is preferable.

The compound having a maleimide group is not particularly limited as long as the compound has one or more maleimide groups in one molecular, but is preferably the compound having more than two maleimide groups and examples include 3,4,4′-triaminodiphenylmethane, the multifunctional maleimide compound obtained by the reaction of triaminophenol and the like and maleic anhydride, tris-(4-aminophenyl)-phosphate, tris(4-aminophenyl)-phosphate, the maleimide compound obtained by the reaction of tris(4-aminophenyl)thiophosphate and maleic anhydride, the trismaleimide compounds such as tris(4-maleimidephenyl)methane, bis(3,4-dimaleimidephenyl)methane, tetramaleimidebenzophenone, tetramaleimidenaphthalene, the tetramaleimide compounds such as maleimide obtained by the reaction of triethylenetetramine and maleic anhydride, phenolnovolac type maleimide resin, isopropylidenebis(phenoxyphenylmaleimide)phenylmaleimidearalkyl resin, biphenylene type phenylmaleimidearalkyl resin. The commercial products of the compound having a maleimide group are MIR-3000, MIR-5000 (all manufactured by Nippon Kayaku Co., Ltd.), BMI-70, BMI-80 (all manufactured by K⋅I Chemical Industry Co., Ltd.), BMI-1000, BMI-2000, BMI-3000 (all manufactured by Daiwa Kasei Industry Co., Ltd.) and so on.

Because the compound having a maleimide group is self-crosslinked between the maleimide groups by the action of the radical initiator, the resin composition obtained by using the isocyanate-modified polyimide resin having an amino group on the end, the compound having a maleimide group and the radical initiator may produce the cured products where the maleimide groups are self-crosslinked by heating and the polyimide resin and the maleimide resin are copolymerized.

The radical initiator used for self-crosslinking between the maleimide groups may be the peroxides such as dicumylperoxide and dibutylperoxide and the azo compounds such as 2,2′-azobis(isobutyronitrile) and 2,2′-azobis(2,4-dimethylvaleronitrile) and so on. The amount of the radical initiator added in the resin composition of the present invention containing the compound having a maleimide group is 0.1 to 10 mass % based on the compound having a maleimide group.

Examples of the compound having an epoxy group includes the same one as “the compound having an epoxy group as the reactive compound of the first embodiment reactive with the acid anhydride group” described above and the same catalyst and the same compound used together may be also used.

The compound having a carboxy group is not particularly limited as long as the compound has one or more carboxy groups in one molecular, but is preferably a compound having more than two carboxy groups. Examples of the compound having a carboxy group include the liner alkyl dioic acids such as butanedioic acid, pentanedioic acid, hexanedioic acid, heptanedioic acid, octanedioic acid, nonanedioic acid, decanedioic acid and malic acid, the arkyltricarboxylic acids such as 1,3,5-pentanetricarboxylic acid and citric acid, phthalic acid, hexahydrophthalic acid, methylhexahydrophthalic acid, tetrahydrophthalic acid, methyltetrahydrophthalic acid, cyclohexanetricarboxylic acid, nadic acid and methylnadic acid.

The content of the reactive compound of the first embodiment in the resin composition of the present invention is preferably the amount that the equivalent of the reactive group of the reactive compound of the first embodiment is 0.1 to 500 equivalents based on one equivalent of the terminal functional group of the isocyanate-modified polyimide resin. When the equivalent of the reactive group of the reactive compound of the first embodiment is within the range aforementioned, thereby the cured products of the resin composition having crosslinking density that may provide excellent various physical properties. The equivalent mentioned here is a value calculated from the used amount of each raw material when synthesizing the isocyanate-modified polyimide resin.

Note that when the isocyanate-modified polyimide resin has both the acid anhydride group and the amino group on both ends, the both of the reactive compound of the first embodiment reactive with the acid anhydride group and the reactive compound of the first embodiment reactive with the amino group also may be used together.

The nonreactive compound of the first embodiment is not limited as long as the compound does not react with the isocyanate-modified polyimide resin. The organic solvent and the like are included in this category. The resin composition containing the organic solvent is also called “varnish” and is the preferable embodiment for the application where the handling ability of the resin composition is improved by diluting with the organic solvent and the like.

Examples of the organic solvent include γ-butyrolactone, amido solvents such as N-methylpyrolidone, N,N-dimethylformaide, N,N-dimethylacetamide and N,N-dimethylimidazolidinone, sulfones such as tetramethylenesulfone, ether solvents such as diethyleneglycoldimethylether, diethyleneglycoldiethylether, propyleneglycol, propyleneglycolmonomethylether, propyleneglycolmonomethylethermonoacetate and propyleneglycolmonobutylether, ketone solvents such as methylethylketone, methylisobutylketone, cyclopentanone and cyclohexanone and aromatic solvents such as toluene and xylene.

The organic solvent is used so that the concentration of the solid contents except for the organic solvent in the resin composition is generally 10 to 80 mass %, preferably 20 to 70 mass %.

Because the compound having a thiol group and the compound having an amino group described in the paragraph of “the reactive compound of the first embodiment reactive with the acid anhydride group” do not react with amino group, these compounds may be used together with the isocyanate-modified polyimide resin having an amino group on the end as the nonreactive compound of the first embodiment to obtain the resin composition. Because the compound having a maleimide group and the compound having a carboxy group described in the paragraph of “the reactive compound of the first embodiment reactive with the amino group” do not react with acid anhydride group, these compounds may be used together with the isocyanate-modified polyimide resin having an acid anhydride group on the end as the nonreactive compound of the first embodiment to obtain the resin composition.

Like the description in the paragraphs of the compound having a maleimide group and the compound having an epoxy group of the reactive compound of the first embodiment, it is the preferable embodiment of the resin composition of the present invention that the nonreactive compound of the first embodiment is self-crosslinked and that several nonreactive compounds of the first embodiment are copolymerized with each other. By self-crosslinking or copolymerizing the nonreactive compounds of the first embodiment in the resin composition, the cured products of the nonreactive compound containing the isocyanate-modified polyimide resin which is not bonded can be obtained.

Next, as the second embodiment, the resin composition containing the terminal-modified isocyanate-modified polyimide resin and the compound except for the terminal-modified isocyanate-modified polyimide resin is described.

The compound except for the terminal-modified isocyanate-modified polyimide resin of the resin composition of the second embodiment is not limited to any one of the compounds reactive with the terminal-modified isocyanate-modified polyimide resin (hereinafter described as “the reactive compound of the second embodiment”) and the compound nonreactive with the terminal-modified isocyanate-modified polyimide resin (hereinafter described as “the nonreactive compound of the second embodiment”).

The reactive compound of the second embodiment is a compound reactive with the functional group that the terminal-modified isocyanate-modified polyimide resin has on the end. Because the functional group that the terminal-modified isocyanate-modified polyimide resin has on the end depends on the compound used for the terminal-modification, in consideration of the terminal functional group of the terminal-modified isocyanate-modified polyimide resin,

the compound reactive with the terminal functional group should be selected as the reactive compound of the second embodiment.

For example, when the both ends of isocyanate-modified polyimide resin having an amino group are modified by tetrabasic acid dianhydride, the both ends of the terminal-modified isocyanate-modified polyimide resin are changed to the acid anhydride group. Therefore, the reactive compound of the second embodiment reactive with the acid anhydride group may be the same compound as the reactive compound of the first embodiment reactive with the terminal acid anhydride group of the isocyanate-modified polyimide resin, and the same catalyst, the same compound usable together may be also used.

When the both ends of the isocyanate-modified polyimide resin having an acid anhydride group are modified by diamino compound, the both ends of the terminal-modified isocyanate-modified polyimide resin are changed to the amino group. Therefore, the reactive compound of the second embodiment reactive with the amino group includes the same compound as the reactive compound of the first embodiment reactive with the terminal amino group of the isocyanate-modified polyimide resin.

As other examples, the terminal of the terminal-modified isocyanate-modified polyimide resin obtained by using the epoxy resin, the compound having a maleimide group (including the maleimide resin), the isocyanate resin, the allyl resin, the benzoxazine resin and the acryloyl resin for the terminal modification of the isocyanate-modified polyimide resin respectively may be the epoxy group, the maleimide group, the isocyanate group, the allyl group, the benzoxazine group and the acryloyl group respectively. Therefore, the compound reactive with these terminal functional groups may be used as the reactive compound of the second embodiment and the catalyst and the like used generally in the reaction of the terminal functional group aforementioned and the reactive compound can be used together.

The compound having an acryloyl group is preferably used together with the terminal-modified isocyanate-modified polyimide resin having an acryloyl group on the end as the reactive compound of the second embodiment. Examples include alkyl(meth)acrylates such as 2-ethylhexyl(meth)acrylate and cyclohexyl(meth)acrylate; hydroxyalkyl(meth)acrylates such as 2-hydroxyethyl(meth)acrylate and 2-hydroxypropyl(meth)acrylate; mono or di(meth)acrylate of alkylene oxide derivatives such as ethyleneglycol, propyleneglycol, diethyleneglycol and dipropyleneglycol; poly(meth)acrylate of polyalcohols or ethyleneoxide or propyleneoxide adducts thereof such as hexanediol, trimethylolpropane, pentaerythritol, ditrimethylolpropane, dipentaerythritol, trishydroxyethylisocyanurate; (meth)acrylates of ethyleneoxide or propyleneoxide adduct of phenol such as phenoxyethyl(meth)acrylate, polyethoxydi(meth)acrylate of bisphenol A; (meth)acrylate of glycidylethers such as glycerindiglycidylether, trimethylolpropanetriglycidylether, triglycidylisocyanurate; and melamine(meth)acrylate. The polymerization initiator and the like usable for the (co)polymerization of the compound having an acryloyl group also can be used together.

The content of the reactive compound of the second embodiment in the resin composition of the present invention is preferably the amount that the equivalent of the reactive group of the reactive compound of the second embodiment is 0.1 to 500 equivalents based on one equivalent of the terminal functional group of the terminal-modified isocyanate-modified polyimide resin. When the equivalent of the reactive group of the reactive compound of the second embodiment is within the range aforementioned, thereby the cured products of the resin composition having crosslinking density may produce excellent various physical properties. The equivalent mentioned here is the value calculated from the used amount of each raw material when synthesizing the terminal-modified isocyanate-modified polyimide resin.

Note that when the terminal-modified isocyanate-modified polyimide resin has different functional groups on both ends, more than one reactive compounds of the second embodiment reactive with respective functional groups also can be used together.

The nonreactive compound of the second embodiment is not limited as long as the compound does not react with the terminal-modified isocyanate-modified polyimide resin. The organic solvent and the like are included in this category. The resin composition containing the organic solvent is also called “varnish” and is the preferable embodiment for the application where the handling ability of the resin composition is improved by diluting with the organic solvent and the like.

Examples and the content in the resin composition of the organic solvent are the same as the organic solvent and the content described in the paragraph of the nonreactive compound of the first embodiment.

The conventional additive also can be used together with the resin composition of the present invention. Examples usable together includes the curing agent for the epoxy resin, polybutadiene and modified polybutadiene, modified acrylonitrile copolymer, polyphenylene ether, polystyrene, polyethylene, polyimide, fluorocarbon resin, maleimide compound, cyanate ester compound, silicone gel, silicone oil and the inorganic fillers such as silica, alumina, calcium carbonate, quartz powder, aluminum powder, graphite, talc, clay, iron oxide, titanium oxide, aluminum nitride, asbestos, mica, glass powder, the surface treatment agents for the filler such as the silane coupling agent, the releasing agent, the coloring agents such as carbon black, phtharocyanine blue and phtharocyanine green. The content of these additives is preferably in the range of equal to or less than 1,000 mass parts, more preferably equal to or less than 700 mass parts based on 100 mass parts of the resin composition.

The curing time and the curing temperature of the resin composition of the present invention may be selected in consideration of the combination and the like of the functional group that the (terminal-modified) isocyanate-modified polyimide resin has on the both ends and the reactive group of the reactive compound. For example, the curing temperature of the resin composition containing the maleimide resin and the resin composition containing the epoxy resin is preferably 120 to 250° C. and the curing time is generally several tens minutes to several hours.

The preparing method of the resin composition of the present invention is not particularly limited. The resin composition may be prepared by only mixing each component homogeneously or by producing the prepolymer. For example, the prepolymer can be produced by heating the (terminal-modified) isocyanate-modified polyimide resin and the reactive compound in the presence or absence of the catalyst, in the presence or absence of the solvent. The mixture of each component or the production of the prepolymer are carried out by using the extruder, the kneader, the roll and the like in the absence of the solvent and by using the reaction kettle with the stirring device and the like in the presence of the solvent.

The prepreg can be obtained by impregnating the reinforcing fiber such as glass fiber, carbon fiber, polyester fiber, polyamide fiber, alumina fiber with the resin composition of the present invention which is melted by heating and whose viscosity is lowered. The prepreg also can be obtained by heating to dry after impregnating the reinforcing fiber with the varnish aforementioned.

After cutting the prepreg described above into the desired form and laminating the prepreg with the copper foil and the like as necessary, the prepreg-laminated article is cured by heating the resin composition under pressure by the press forming method, the autoclave method, the sheet winding method and the like to obtain the substrates of the present invention such as the laminated board for the electric/electronic equipment (the printed wiring board) and the carbon fiber-reinforced material.

Also, after coating the resin composition on the copper foil and drying the solvent, the polyimide film or the LCP (liquid crystal polymer) is laminated. After hot-press the laminate is thermally cured to obtain the substrate of the present invention. In some cases, the substrate of the present invention is also obtained by laminating the copper foil after coating the resin composition on the polyimide film or the LCP (liquid crystal polymer).

### EXAMPLES

The present invention will be explained in more detail with the Examples and the Comparative Examples hereinafter, but is not limit to these Examples. In the Examples the “part” means part by mass and “%” means % by mass respectively unless specified otherwise.

### Example 1 (Synthesis of Isocyanate-Modified Polyimide Resin of Present Invention)

Into the reaction vessel of 300 ml provided with the thermometer, the efflux cooler, the Dean-Stark apparatus, the raw material inlet port, the nitrogen introducing device, and the stirring device 5.28 parts of BAFL (9,9-bis(4-aminophenyl)fluorene, manufactured by JFE Chemical Corporation, molecular weight 348.45 g/mol), 13.28 parts of PRIAMINE1075 (C36 dimerdiamine, manufactured by Croda Japan K.K., molecular weight 534.38 g/mol), 14.89 parts of ODPA (oxydiphthalic anhydride, manufactured by Manac Incorporation, molecular weight 310.22 g/mol), 74.45 parts of anisole, 0.97 parts of triethylamine and 19.80 parts of toluene were added and heated to 120° C. to dissolve the raw materials. While the water generated with the cyclization of amic acid was removed by azeotropically boiling with toluene, the solution was reacted at 135° C. for 4 hours. After the generation of water was stopped, the intermediate polyimide resin solution was obtained by continuing to remove the remained triethylamine and toluene at 140° C. The mole ratio (the number of moles of the acid anhydride component/the number of moles of the diamine component) of the diamine component (the (b) component and the (d) component) and the acid anhydride component (the (c) component) used for the synthesis of the intermediate polyimide resin was 1.20.

Next, to the intermediate polyimide resin solution obtained above 1.48 parts of TMDI (trimethylhexamethylenediisocyanate, manufactured by Degussa-Huls AG, molecular weight 210.28 g/mol) and 3.30 parts of anisole were added and heated at 130° C. for 3 hours to obtain the isocyanate-modified polyimide resin solution (A-1) (nonvolatile component 30.1%). The final mole ratio of the raw material components of the isocyanate-modified polyimide resin obtained above (the number of moles of the acid anhydride component/(the number of moles of the diamine component+the number of moles of the diisocyanate component)) was 1.02.

### Example 2 (Synthesis of Isocyanate-Modified Polyimide Resin of Present Invention))

Into the reaction vessel of 300 ml provided with the thermometer, the efflux cooler, the Dean-Stark apparatus, the raw material inlet port, the nitrogen introducing device and the stirring device, 5.37 parts of BAFL (9,9-bis(4-aminophenyl)fluorene, manufactured by JFE Chemical Corporation, molecular weight 348.45 g/mol), 13.14 parts of PRIAMINE1075 (C36 dimerdiamine, manufactured by Croda Japan K.K., molecular weight 534.38 g/mol), 14.89 parts of ODPA (oxydiphthalic anhydride, manufactured by Manac Incorporation, molecular weight 310.22 g/mol), 74.35 parts of anisole, 0.97 parts of triethylamine and 19.79 parts of toluene were added and heated to 120° C. to dissolve the raw materials. While the water generated with the cyclization of amic acid was removed by azeotropically boiling with toluene, the solution was reacted at 135° C. for 4 hours. After the generation of water was stopped, the intermediate polyimide resin solution was obtained by continuing to remove the remained triethylamine and toluene at 140° C. The mole ratio (the number of moles of the acid anhydride component/the number of moles of the diamine component) of the diamine component (the (b) component and the (d) component) and the acid anhydride component (the (c) component) used for the synthesis of the intermediate polyimide resin was 1.20.

Next, to the intermediate polyimide resin solution obtained above, 1.19 parts of HDI (hexamethylenediisocyanate, manufactured by Asahi Kasei Corporation, molecular weight 168.20 g/mol) and 2.64 parts of anisole were added and heated at 130° C. for 3 hours to obtain the isocyanate-modified polyimide resin solution (A-2) (nonvolatile component 30.0%). The final mole ratio of the raw material components of the isocyanate-modified polyimide resin obtained above (the number of moles of the acid anhydride component/(the number of moles of the diamine component+the number of moles of the diisocyanate component)) was 1.02.

### Example 3 (Synthesis of Isocyanate-Modified Polyimide Resin of Present Invention))

Into the reaction vessel of 300 ml provided with the thermometer, the efflux cooler, the Dean-Stark apparatus, the raw material inlet port, the nitrogen introducing device and the stirring device, 5.25 parts of BAFL (9,9-bis(4-aminophenyl)fluorene, manufactured by JFE Chemical Corporation, molecular weight 348.45 g/mol), 13.32 parts of PRIAMINE1075 (C36 dimerdiamine, manufactured by Croda Japan K.K., molecular weight 534.38 g/mol), 14.89 parts of ODPA (oxydiphthalic anhydride, manufactured by Manac Incorporation, molecular weight 310.22 g/mol), 74.48 parts of anisole, 0.97 parts of triethylamine and 19.80 parts of toluene were added and heated to 120° C. to dissolve the raw materials. While the water generated with the cyclization of amic acid was removed by azeotropically boiling with toluene, the solution was reacted at 135° C. for 4 hours. After the generation of water was stopped, the intermediate polyimide resin solution was obtained by continuing to remove the remained triethylamine and toluene at 140° C. The mole ratio (the number of moles of the acid anhydride component/the number of moles of the diamine component) of the diamine component (the (b) component and the (d) component) and the acid anhydride component (the (c) component) used for the synthesis of the intermediate polyimide resin was 1.20.

Next, to the intermediate polyimide resin solution obtained above 1.57 parts of IPDI (isophoronediisocyanate, manufactured by Degussa-Huls AG, molecular weight 222.29 g/mol) and 3.49 parts of anisole were added and heated at 130° C. for 3 hours to obtain the isocyanate-modified polyimide resin solution (A-3) (nonvolatile component 30.0%). The final mole ratio of the raw material components of the isocyanate-modified polyimide resin obtained above (the number of moles of the acid anhydride component/(the number of moles of the diamine component+the number of moles of the diisocyanate component)) was 1.02.

### Example 4 (Synthesis of Isocyanate-Modified Polyimide Resin of Present Invention))

Into the reaction vessel of 300 ml provided with the thermometer, the efflux cooler, the Dean-Stark apparatus, the raw material inlet port, the nitrogen introducing device and the stirring device, 10.16 parts of BAPP (2,2-bis[4-(4-aminophenoxy)phenyl]propane, manufactured by Wakayama Seika Kogyo Co., Ltd., molecular weight 410.52 g/mol), 12.42 parts of PRIAMINE1075 (C36 dimerdiamine, manufactured by Croda Japan K.K., molecular weight 534.38 g/mol), 8.73 parts of PMDA (pyromellitic dianhydride, manufactured by MITSUBISHI GAS CHEMICAL COMPANY, INC., molecular weight 218.12 g/mol), 69.69 parts of anisole, 0.81 parts of triethylamine and 19.16 parts of toluene were added and heated to 120° C. to dissolve the raw materials. While the water generated with the cyclization of amic acid was removed by azeotropically boiling with toluene, the solution was reacted at 135° C. for 4 hours. After the generation of water was stopped, the intermediate polyimide resin solution was obtained by continuing to remove the remained triethylamine and toluene at 140° C. The mole ratio (the number of moles of the diamine component/the number of moles of the acid anhydride component) of the diamine component (the (b) component and the (d) component) and the acid anhydride component (the (c) component) used for the synthesis of the intermediate polyimide resin was 1.20.

Next, to the intermediate polyimide resin solution obtained above 1.19 parts of HDI (hexamethylenediisocyanate, manufactured by Asahi Kasei Corporation, molecular weight 168.20 g/mol) and 2.64 parts of anisole were added and heated at 130° C. for 3 hours to obtain the isocyanate-modified polyimide resin solution (A-4) (nonvolatile component 30.1%). The final mole ratio of the raw material components of the isocyanate-modified polyimide resin obtained above (the number of moles of the diamine component/(the number of moles of the acid anhydride component+the number of moles of the diisocyanate component)) was 1.02.

### Example 5 (Synthesis of Terminal-Modified Isocyanate-Modified Polyimide Resin of Present Invention))

Into the reaction vessel of 300 ml provided with the thermometer, the efflux cooler, the Dean-Stark apparatus, the raw material inlet port, the nitrogen introducing device and the stirring device, 9.13 parts of BAPP (2,2-bis[4-(4-aminophenoxy)phenyl]propane, manufactured by Wakayama Seika Kogyo Co., Ltd., molecular weight 410.52 g/mol), 13.76 parts of PRIAMINE1075 (C36 dimerdiamine, manufactured by Croda Japan K.K., molecular weight 534.38 g/mol), 11.77 parts of BPDA (biphenyltetracarboxylic dianhydride, manufactured by Mitsubishi Chemical Corporation, molecular weight 294.22 g/mol), 77.15 parts of anisole, 0.81 parts of triethylamine and 20.14 parts of toluene were added and heated to 120° C. to dissolve the raw materials. While the water generated with the cyclization of amic acid was removed by azeotropically boiling with toluene, the solution was reacted at 135° C. for 4 hours. After the generation of water was stopped, the intermediate polyimide resin solution was obtained by continuing to remove the remained triethylamine and toluene at 140° C. The mole ratio (the number of moles of the diamine component/the number of moles of the acid anhydride component) of the diamine component (the (b) component and the (d) component) and the acid anhydride component (the (c) component) used for the synthesis of the intermediate polyimide resin was 1.20.

Next, to the intermediate polyimide resin solution obtained above 1.19 parts of HDI (hexamethylenediisocyanate, manufactured by Asahi Kasei Corporation, molecular weight 168.20 g/mol) and 2.64 parts of anisole were added and heated at 130° C. for 3 hours to obtain the isocyanate-modified polyimide resin solution (A-5). The final mole ratio of the raw material components of the isocyanate-modified polyimide resin obtained above (the number of moles of the diamine component/(the number of moles of the acid anhydride component+the number of moles of the diisocyanate component)) was 1.02. Next, in the isocyanate-modified polyimide resin solution (A-5) 0.08 parts of maleic anhydride (molecular weight 98.06 g/mol), 0.3 parts of triethylamine and 5.2 parts of toluene were added and reacted at 135° C. for 4 hours. After the generation of water was stopped, the terminal-modified isocyanate-modified polyimide resin solution (B-5) (nonvolatile component 30.2%) obtained by modifying the both ends of the isocyanate-modified polyimide resin with maleic anhydride was obtained by removing the remained triethylamine and toluene at 140° C.

### Example 6 (Synthesis of Isocyanate-Modified Polyimide Resin of Present Invention))

Into the reaction vessel of 300 ml provided with the thermometer, the efflux cooler, the Dean-Stark apparatus, the raw material inlet port, the nitrogen introducing device and the stirring device, 1.22 parts of BAFL (9,9-bis(4-aminophenyl)fluorene, manufactured by JFE Chemical Corporation, molecular weight 348.45 g/mol), 10.38 parts of Diamine18(C18 diamine, manufactured by OKAMURA OIL MILL, LTD., molecular weight 284.53 g/mol), 14.89 parts of ODPA (oxydiphthalic anhydride, manufactured by Manac Incorporation, molecular weight 310.22 g/mol), 58.98 parts of anisole, 0.97 parts of triethylamine and 17.78 parts of toluene were added and heated to 120° C. to dissolve the raw materials. While the water generated with the cyclization of amic acid was removed by azeotropically boiling with toluene, the solution was reacted at 135° C. for 4 hours. After the generation of water was stopped, the intermediate polyimide resin solution was obtained by continuing to remove the remained triethylamine and toluene at 140° C. The mole ratio (the number of moles of the acid anhydride component/the number of moles of the diamine component) of the diamine component (the (b) component and the (d) component) and the acid anhydride component (the (c) component) used for the synthesis of the intermediate polyimide resin was 1.20.

Next, to the intermediate polyimide resin solution obtained above 1.19 parts of HDI (hexamethylenediisocyanate, manufactured by Asahi Kasei Corporation, molecular weight 168.20 g/mol) and 2.64 parts of anisole were added and heated at 130° C. for 3 hours to obtain the isocyanate-modified polyimide resin solution (A-6) (nonvolatile component 30.0%). The final mole ratio of the raw material components of the isocyanate-modified polyimide resin obtained above (the number of moles of the acid anhydride component/(the number of moles of the diamine component+the number of moles of the diisocyanate component)) was 1.02.

### Comparative Example 1 (Synthesis of Polyimide Resin for Comparison)

Into the reaction vessel of 300 ml provided with the thermometer, the efflux cooler, the Dean-Stark apparatus, the raw material inlet port, the nitrogen introducing device and the stirring device, 7.53 parts of BAPP (2,2-bis[4-(4-aminophenoxy)phenyl]propane, manufactured by Wakayama Seika Kogyo Co., Ltd., molecular weight 410.52 g/mol), 12.43 parts of PRIAMINE1075 (C36 dimerdiamine, manufactured by Croda Japan K.K., molecular weight 534.38 g/mol), 12.41 parts of ODPA (oxydiphthalic anhydride, manufactured by Manac Incorporation, molecular weight 310.22 g/mol), 72.37 parts of anisole, 0.81 parts of triethylamine and 19.51 parts of toluene were added and heated to 120° C. to dissolve the raw materials. While the water generated with the cyclization of amic acid was removed by azeotropically boiling with toluene, the solution was reacted at 135° C. for 4 hours. After the generation of water was stopped, the polyimide resin solution for comparison (R-1) (nonvolatile component 30.0%) was obtained by continuing to remove the remained triethylamine and toluene at 140° C. The final mole ratio of the raw material components of the polyimide resin for comparison obtained above (the number of moles of the acid anhydride component/the number of moles of the diamine component) was 1.05.

### Comparative Example 2 (Synthesis of Polyimide Resin for Comparison)

Into the reaction vessel of 300 ml provided with the thermometer, the efflux cooler, the Dean-Stark apparatus, the raw material inlet port, the nitrogen introducing device and the stirring device, 6.45 parts of BAFL (9,9-bis(4-aminophenyl)fluorene, manufactured by JFE Chemical Corporation, molecular weight 348.45 g/mol), 11.71 parts of PRIAMINE1075 (C36 dimerdiamine, manufactured by Croda Japan K.K., molecular weight 534.38 g/mol), 12.41 parts of ODPA (oxydiphthalic anhydride, manufactured by Manac Incorporation, molecular weight 310.22 g/mol), 68.34 parts of anisole, 0.81 parts of triethylamine and 18.99 parts of toluene were added and heated to 120° C. to dissolve the raw materials. While the water generated with the cyclization of amic acid was removed by azeotropically boiling with toluene, the solution was reacted at 135° C. for 4 hours. After the generation of water was stopped, the polyimide resin solution for comparison (R-2) (nonvolatile component 30.2%) was obtained by continuing to remove the remained triethylamine and toluene at 140° C. The final mole ratio of the raw material components of the polyimide resin for comparison obtained above (the number of moles of the acid anhydride component/the number of moles of the diamine component) was 1.02.

### Examples 7 to 12, Comparative Examples 3 and 4 (Preparation of Resin Composition)

The polyimide resin solution (A-1) to (A-4), (B-5) and (A-6) obtained in Examples 1 to 6, the polyimide resin solution for comparison (R-1) and (R-2) obtained in Comparative Examples 1 and 2, MIR3000-70MT (the maleimide resin having a biphenyl skeleton, manufactured by Nippon Kayaku Co., Ltd., nonvolatile component 70.0%) as the compound having a maleimide group, dicumylperoxide (DCP) as the radical initiator, NC-3000 (epoxy resin having a biphenyl skeleton, manufactured by Nippon Kayaku Co., Ltd. epoxy equivalent 277 g/eq, softening point 60° C.) as the epoxy resin and C11Z-A manufactured by SHIKOKU CHEMICALS CORPORATION as the curing accelerator were mixed with the blending amount shown in Table 1 (the unit was “part”, the number of parts of the polyimide resin and the compound having a maleimide group were the number of parts of the solution including the solvent) to obtain the resin composition of the present invention and the resin composition for comparison.

TABLE 1
Composition of Resin Composition

| | | | | | | | Comparative | Comparative |
|---|---|---|---|---|---|---|---|---|
| | Example 7 | Example 8 | Example 9 | Example 10 | Example 11 | Example 12 | Example 3 | Example 4 |
| A-1 | 50 | | | | | | | |
| A-2 | | 50 | | | | | | |
| A-3 | | | 50 | | | | | |
| A-4 | | | | 50 | | | | |
| B-5 | | | | | 50 | | | |
| A-6 | | | | | | 50 | | |
| R-1 | | | | | | | 50 | |
| R-2 | | | | | | | | 50 |
| MIR3000-70MT | 9.18 | 9.18 | 9.18 | 9.18 | 9.18 | 9.18 | 9.18 | 9.18 |
| DCP | 0.21 | 0.21 | 0.21 | 0.21 | 0.21 | 0.21 | 0.21 | 0.21 |
| NC-3000 | 0.2 | 0.2 | 0.2 | | | 0.2 | | |
| C11Z-A | 0.002 | 0.002 | 0.002 | | | 0.002 | | |

(Evaluation of Adhesive Strength)

By using the resin compositions obtained in Examples 7 to 12, Comparative Examples 3 and 4, the adhesive strength to the copper foil and thermal property of the cured product of the resin composition were evaluated.

The resin compositions obtained above were coated on the rough surface of the copper foil CF-T4X-SV-18 manufactured by FUKUDA METAL FOIL & POWDER Co., Ltd. (hereinafter described as “T4X”) by using the automatic applicator respectively and dried by heating at 120° C. for 10 minutes. The thickness of the film after drying was 30 μm. On the film on the copper foil obtained above, another T4X was superimposed with the rough surface and vacuum-pressed with a pressure of 3 Mpa at 200° C. for 60 minutes. The test piece obtained was cut out by the width of 10 mm and the 90° peeling strength between the copper foils was measured (the peeling speed was 50 mm/min) by using Auto Graph AGS-X-500N (manufactured by Shimazu Corporation) to evaluate the adhesive strength of the copper foil. When the samples were observed visually after test, the cohesive failure was occurred in all samples. The results were shown in Tables 2 and 3.

(Evaluation of Thermal Property)

The test piece made by the same method as the method in “Evaluation of Adhesive Strength” described above was floated in the solder bath heated at 288° C. by using POT-200C (manufactured by TAIYO ELECTRIC IND. CO., LTD.). Thermal property was evaluated by the time until the blister occurred. The results were shown in Tables 2 and 3.

(Evaluation of Mechanical Property and Dielectric Property)

The films having a thickness of 100 μm after drying were formed on the rough surface of T4X respectively by the same method as the method in “Evaluation of Adhesive Strength” described above, provided that the coating thickness of the automatic applicator was changed, and the formed film was cured by heating at 200° C. for 60 minutes. The copper foil was removed by etching with iron (III) chloride solution having a liquid specific gravity of 45 baume degree. After washing with ion-exchanged water, the film-like cured products were obtained respectively by drying at 105° C. for 10 minutes. As for the film-like cured products, stress at breaking point, elongation at breaking point and elastic modulus were measured by using Auto Graph AGS-X-500N (manufactured by Shimazu Corporation) and dielectric property at 10 Ghz were measured by using Network Analyzer 8719E (manufactured by Agilent Technologies Japan, Ltd.) and by the cavity resonance method. The results were shown in Tables 2 and 3.

TABLE 2
Evaluation Results of Resin Composition

| | | Unit | Example 7 | Example 8 | Example 9 | Example 10 |
|---|---|---|---|---|---|---|
| Adhesive strength | T4X | N/cm | 10.2 | 11.3 | 8.2 | 9.7 |
| Mechanical strength | Stress at breaking | Mpa | 32.6 | 32.2 | 39.2 | 42.9 |
| | point | | | | | |
| | Elongation at breaking | % | 7.6 | 8.3 | 5.6 | 4.2 |
| | point | | | | | |
| | Elastic modulus | Gpa | 0.9 | 1.0 | 1.1 | 1.4 |
| Thermal property | Solder bath heated at | sec | >100 | >100 | >100 | >100 |
| | 288° C. | | | | | |
| Dielectric Property | Dielectric constant at | — | 2.35 | 2.38 | 2.31 | 2.58 |
| | 10 GHz | | | | | |
| | Dielectric loss tangent | — | 0.0009 | 0.0016 | 0.0017 | 0.0019 |
| | at 10 GHz | | | | | |

TABLE 3
Evaluation Results of Resin Composition

| | | | | | Comparative | Comparative |
|---|---|---|---|---|---|---|
| | | Unit | Example 11 | Example 12 | Example3 | Example4 |
| Adhesive strength | T4X | N/cm | 9.8 | 10.1 | 9.1 | 6.4 |
| Mechanical strength | Stress at breaking | Mpa | 41.2 | 42.1 | 14.7 | 8.0 |
| | point | | | | | |
| | Elongation at breaking | % | 5.5 | 4.1 | 0.6 | 0.3 |
| | point | | | | | |
| | Elastic modulus | Gpa | 1.6 | 2.0 | 2.0 | 2.1 |
| Thermal property | Sokler bath heated at | sec | >100 | >100 | 30 | >100 |
| | 288° C. | | | | | |
| Dielectric Property | Dielectric constant at | — | 2.55 | 2.61 | 2.62 | 2.71 |
| | 10 GHz | | | | | |
| | Dielectric loss tangent | — | 0.0019 | 0.0019 | 0.0027 | 0.0026 |
| | at 10 GHz | | | | | |

From the results shown in Tables 2 and 3, the resin composition of the present invention was excellent in all of adhesive strength, mechanical property, thermal property and dielectric constant. In contrast the resin composition for comparison was inferior in mechanical property and inferior in any one of adhesive strength or thermal property in addition to having a high dielectric loss tangent.

### Example 13 (Synthesis of Isocyanate-Modified Polyimide Resin of Present Invention)

Into the reaction vessel of 300 ml provided with the thermometer, the efflux cooler, the Dean-Stark apparatus, the raw material inlet port, the nitrogen introducing device and the stirring device, 7.70 parts of BAFL (9,9-bis(4-aminophenyl)fluorene, manufactured by JFE Chemical Corporation, molecular weight 348.45 g/mol), 10.64 parts of PRIAMINE1075 (C36 dimerdiamine, manufactured by Croda Japan K.K., molecular weight 534.38 g/mol), 12.41 parts of ODPA (oxydiphthalic anhydride, manufactured by Manac Incorporation, molecular weight 310.22 g/mol), 68.43 parts of anisole, 0.81 parts of triethylamine and 19.00 parts of toluene were added and heated to 120° C. to dissolve the raw materials. While the water generated with the cyclization of amic acid was removed by azeotropically boiling with toluene, the solution was reacted at 135° C. for 4 hours. After the generation of water was stopped, the intermediate polyimide resin solution was obtained by continuing to remove the remained triethylamine and toluene at 140° C. The mole ratio (the number of moles of the diamine component/the number of moles of the acid anhydride component) of the diamine component (the (b) component and the (d) component) and the acid anhydride component (the (c) component) used for the synthesis of the intermediate polyimide resin was 1.05.

Next, to the intermediate polyimide resin solution obtained above 0.26 parts of IPDI (isophoronediisocyanate, manufactured by Degussa-Huls AG, molecular weight 222.29 g/mol) and 0.58 parts of anisole were added and heated at 130° C. for 3 hours to obtain the isocyanate-modified polyimide resin solution (A-7) (nonvolatile component 30.1%). The final mole ratio of the raw material components of the isocyanate-modified polyimide resin obtained above (the number of moles of the diamine component/(the number of moles of the acid anhydride component+the number of moles of the diisocyanate component)) was 1.02.

### Examples 14 to 19 (Preparation of Resin Composition)

The polyimide resin solution (A-1), (A-3) and (A-7) obtained in Examples 1, 3 and 13, MIR3000-70MT (maleimide resin having a biphenyl skeleton, manufactured by Nippon Kayaku Co., Ltd., nonvolatile component 70.0%) and MIR5000-60T (novolak type maleimide resin, manufactured by Nippon Kayaku Co., Ltd., nonvolatile component 60.0%) as the compound having a maleimide group and dicumylperoxide (DCP) as the radical initiator were mixed with the blending amount shown in Table 4 (the unit was “part”, the number of parts of the polyimide resin and the maleimide resin were the number of parts of the solution including the solvent) to obtain the resin composition of the present invention.

TABLE 4
Composition of Resin Composition

| | Example 14 | Example 15 | Example 16 | Example 17 | Example 18 | Example 19 |
|---|---|---|---|---|---|---|
| A-1 | 57.1 | 50 | | | | |
| A-3 | | | 57.1 | 57.1 | | |
| A-7 | | | | | 57.1 | 50 |
| MIR3000-70MT | 6.12 | 9.18 | 6.12 | | 6.12 | 9.18 |
| MIR5000-60T | | | | 6.12 | | |
| DCP | 0.21 | 0.21 | 0.21 | 0.21 | 0.21 | 0.21 |

(Evaluation of Adhesive Strength, Thermal Property, Mechanical Property and Dielectric Property)

The evaluation samples were made by using the resin composition obtained in Examples 14 to 19 by the same method as the method described above. As for the evaluation samples, adhesive strength, thermal property, mechanical property and dielectric property were evaluated by the same method as the method described above. The results were shown in Table 5.

TABLE 5
Evaluation Results of Resin Composition

| | | Unit | Example 14 | Example 15 | Example 16 | Example 17 | Example 18 | Example 19 |
|---|---|---|---|---|---|---|---|---|
| Adhesive strength | T4X | N/cm | 10.9 | 10.3 | 11.0 | 10.9 | 11.0 | 10.7 |
| Mechanical strength | Stress at breaking | Mpa | 54.8 | 50.5 | 53.4 | 56.7 | 75.1 | 68.7 |
| | point | | | | | | | |
| | Elongation at breaking | % | 9.0 | 4.7 | 8.1 | 9.4 | 8.0 | 6.5 |
| | point | | | | | | | |
| | Elastic modulus | Gpa | 1.5 | 1.7 | 1.4 | 1.32 | 2.1 | 1.8 |
| Thermal property | Solder bath heated at | sec | >100 | >100 | >100 | >100 | >300 | >100 |
| | 288° C. | | | | | | | |
| Dielectric Property | Dielectric constant at | — | 2.6 | 2.46 | 2.59 | 2.48 | 2.64 | 2.601 |
| | 10 GHz | | | | | | | |
| | Dielectric loss tangent | — | 0.0015 | 0.0020 | 0.0019 | 0.0015 | 0.0020 | 0.0022 |
| | at 10 GHz | | | | | | | |

From the results shown in Table 5 the resin composition of the present invention was excellent in all of adhesive strength, mechanical property, thermal property and dielectric constant.

### INDUSTRIAL APPLICABILITY

By using the resin composition containing the isocyanate-modified polyimide resin or the terminal-modified isocyanate-modified polyimide resin of the present invention having a specific structure the printed wiring board and the like excellent in the characteristics such as heat resistance, mechanical property, low dielectric property, adhesiveness can be provided.

1-13. (canceled)

14. An isocyanate-modified polyimide resin being a reaction product of a diisocyanate compound (a) having an isocyanate group and a polyimide resin having an acid anhydride group on both ends,
wherein the polyimide resin is a reaction product of an aliphatic diamino compound (b), a tetrabasic acid dianhydride (c) and an aromatic diamino compound (d),
wherein the aromatic diamino compound (d) comprises at least one selected from the group consisting of the compounds represented by following formulas (6) and (8): 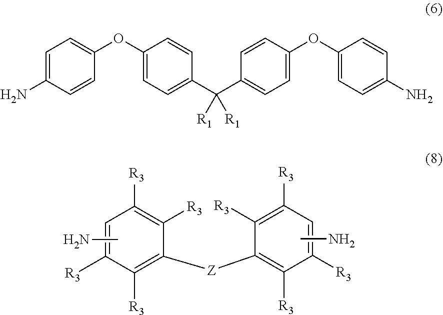
wherein in formula (6), R₁ represents methyl group or trifluoromethyl group, in formula (8), Z represents CH(CH₃), C(CF₃)₂, SO₂, CH₂, O—C₆H₄—O, O, a direct bond or a bivalent linking group represented by following formula (9): 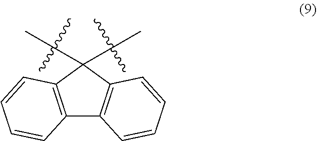
wherein R₃ represents hydrogen atom, methyl group, ethyl group, hydroxy group or trifluoromethyl group, and
wherein the isocyanate-modified polyimide has an acid anhydride group on both ends.

15. The isocyanate-modified polyimide resin according to claim 14, wherein the diisocyanate compound (a) comprises at least one selected from the group consisting of hexamethylenediisocyanate, trimethylhexamethylenediisocyanate and isophoronediisocyanate.

16. The isocyanate-modified polyimide resin according to claim 14, wherein the aliphatic diamino compound (b) comprises at least one of aliphatic diamino compounds having a carbon number of 6 to 36.

17. The isocyanate-modified polyimide resin according to claim 14, wherein the tetrabasic acid dianhydride (c) comprises at least one selected from the group consisting of the compounds represented by following formulas (1) to (4): 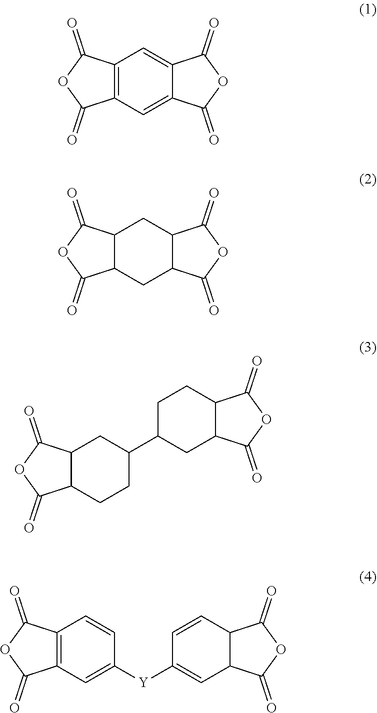
wherein in formula (4), Y represents C(CF₃)₂, SO₂, CO, O, a direct bond or a bivalent linking group represented by following formula (5):

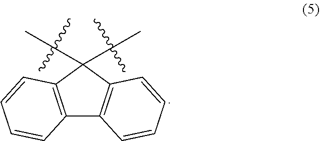 [SMILES: *C1(*)c2ccccc2-c2ccccc21]

18. A terminal-modified isocyanate-modified polyimide resin being a reaction product of the isocyanate-modified polyimide resin having an acid anhydride group on both ends according to claim 14 and a compound having one functional group capable of reacting with the acid anhydride group.

19. A resin composition comprising the isocyanate-modified polyimide resin according to claim 14 and a compound reactive with the isocyanate-modified polyimide resin.

20. A resin composition comprising the terminal-modified isocyanate-modified polyimide resin according to claim 18 and a compound reactive with the terminal-modified isocyanate-modified polyimide resin.

21. The resin composition according to claim 19, wherein the compound reactive with the isocyanate-modified polyimide resin comprises at least one of compounds having a maleimide group.

22. The resin composition according to claim 20, wherein the compound reactive with the terminal-modified isocyanate-modified polyimide resin comprises at least one of compounds having a maleimide group.

23. A resin composition comprising the isocyanate-modified polyimide resin according to claim 14 and a compound nonreactive with the isocyanate-modified polyimide resin.

24. A resin composition comprising the terminal-modified isocyanate-modified polyimide resin according to claim 18 and a compound nonreactive with the terminal-modified isocyanate-modified polyimide resin.

25. A cured product of the resin composition according to claim 19.

26. A cured product of the resin composition according to claim 20.

27. A cured product of the resin composition according to claim 21.

28. A cured product of the resin composition according to claim 22.

29. A cured product of the resin composition according to claim 23.

30. A cured product of the resin composition according to claim 24.

31. A substrate having the cured product according to claim 25.

32. A substrate having the cured product according to claim 26.

33. A substrate having the cured product according to claim 27.
